(19) United States
(12) Patent Application Publication
(10) Pub. No.: US 2024/0006514 A1
(43) Pub. Date: Jan. 4, 2024

(54) SEMICONDUCTOR STRUCTURE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Nan WANG, Shanghai (CN)

(21) Appl. No.: 18/038,106

(22) PCT Filed: Nov. 27, 2020
(86) PCT No.: PCT/CN2020/132024

§ 371 Date: May 22, 2023

(51) Int. Cl. H01L 29/66; H01L 29/78; H01L 29/08

(52) U.S. Cl. CPC H01L 29/66795; H01L 29/66545; H01L 29/7851; H01L 29/6656; H01L 29/0847

(57) ABSTRACT

A semiconductor structure and fabrication method are provided. The fabrication method includes providing a substrate and a fin protruding from the substrate, the fin including stacked structures and each stacked structure including a sacrificial layer and a semiconductor layer on the sacrificial layer; forming a dummy gate across the fin; etching the fin on two sides of the dummy gate to form source/drain recesses; etching the sacrificial layer of the fin at the bottom of the dummy gate exposed by the source/drain recesses to form auxiliary recesses along an extension direction of the fin; forming an isolation layer on the bottoms of the auxiliary recesses without completely filling the auxiliary recesses; and forming a source/drain doped layer completely filling the source/drain recesses, the source/drain doped layer and the isolation layer enclosing an air gap.

### TECHNICAL FIELD

The present disclosure generally relates to the field of semiconductor manufacturing technology and, more particularly, relates to a semiconductor structure and a fabrication method thereof.

### BACKGROUND

The transistor size miniaturization is the development trend of semiconductor structures, but continuous transistor size reduction may also result in a series of technical problems. For example, excessively-thin gate dielectric layer may result in high leakage current between a gate electrode and a channel, and the size reduction may significantly increase the resistance of a polysilicon gate electrode and the like.

Researchers had found that the transistor which is formed by using a high-k gate dielectric layer instead of a gate dielectric layer made of a silicon oxide or silicon oxygen nitride material and by using a metal gate instead of a conventional polysilicon gate material, that is, the high-k metal gate (HKMG) transistor, may effectively solve above problems. On the one hand, the high-k gate dielectric layer may reduce tunneling current between the gate electrode and the channel; on the other hand, the resistivity of the metal gate may be extremely small, which may effectively prevent increase of gate electrode resistance.

However, although the high-k metal gate is introduced, the electrical performance of the semiconductor structure may still need to be improved.

### SUMMARY

The technical solution provided by the present disclosure is to provide a semiconductor structure and a fabrication method thereof, which is beneficial for reducing the parasitic capacitance between the source/drain doped layer and the metal gate.

In order to solve above problem, the technical solution of the present disclosure provides a fabrication method of a semiconductor structure. The method includes providing a substrate and a fin protruding from the substrate, where the fin includes a plurality of stacked structures which are stacked over each other; and each stacked structure includes a sacrificial layer and a semiconductor layer on a top of the sacrificial layer; forming a dummy gate across the fin, where the dummy gate covers a portion of a top of the fin and a portion of a sidewall of the fin; etching the fin on two sides of the dummy gate to form source/drain recesses, where the source/drain recesses expose the fin at a bottom of the dummy gate; etching the sacrificial layer of the fin at the bottom of the dummy gate exposed by the source/drain recesses to form auxiliary recesses on two sides of the sacrificial layer after etching along an extension direction of the fin, where an auxiliary recess includes an opening facing a source/drain recess, and sidewalls on the two sides of the sacrificial layer after etching along the extension direction of the fin form bottoms of the auxiliary recesses; forming an isolation layer on the bottoms of the auxiliary recesses, where the isolation layer does not completely fill the auxiliary recesses; forming a source/drain doped layer completely filling the source/drain recesses, where the source/drain doped layer blocks the opening; and the source/drain doped layer and the isolation layer enclose an air gap; forming a dielectric layer covering sidewalls and a top of the source/drain doped layer and sidewalls of the dummy gate; removing the dummy gate to form a gate recess; after removing the dummy gate, removing a remaining portion of the sacrificial layer, where adjacent semiconductor layers and the isolation layer between the adjacent semiconductor layers enclose a gate through hole; forming a first high-k gate dielectric layer on sidewalls and a bottom surface of the gate recess, and forming a second high-k gate dielectric layer on an inner wall surface of the gate through hole; and forming a first metal gate completely filling the gate recess and forming a second metal gate completely filling the gate through hole.

Optionally, the isolation layer is on the bottoms and sidewalls of the auxiliary recesses; and a step of forming the isolation layer includes forming an isolation film on sidewalls and bottoms of the source/drain recesses, the sidewalls and the bottoms of the auxiliary recesses, and the sidewalls and a top of the dummy gate; forming a filling layer completely filling the auxiliary recesses; removing the isolation film on the sidewalls and the bottoms of the source/drain recesses and the sidewalls and the top of the dummy gate, and forming the isolation layer using a remaining portion of the isolation film; and removing the filling layer.

Optionally, the isolation film is formed by an atomic layer deposition process.

Optionally, the filling layer is formed by a chemical vapor deposition process or an atomic layer deposition process.

Optionally, the filling layer is removed by using a wet etching process.

Optionally, a material of the filling layer is amorphous carbon.

Optionally, along the extension direction of the fin, a depth of the auxiliary recess is from 2 nm to 8 nm.

Optionally, a material of the isolation layer is SiOCN.

Optionally, a step of forming the dummy gate further includes forming a hard mask layer on a top of the dummy gate.

Optionally, after forming the dummy gate and before forming the source/drain recesses, the method further includes forming a spacer on a sidewall of the dummy gate and a sidewall of the hard mask layer.

Optionally, a material of the sacrificial layer is silicon germanium, silicon, germanium, silicon carbide, gallium arsenide or gallium indium; and a material of the semiconductor layer is silicon, germanium, silicon germanium, silicon carbide, gallium arsenide or gallium indium.

Optionally, before forming the dummy gate, the method further includes forming a padding oxide layer on a top of the substrate, the top and the sidewall of the fin.

Correspondingly, the present disclosure further provides a semiconductor structure formed by above-mentioned method. The semiconductor structure includes a substrate and a fin protruding from the substrate, where the fin includes a plurality of stacked semiconductor layers, and a gap is between adjacent semiconductor layers; an isolation layer, where one isolation layer is between the adjacent semiconductor layers and at each of sidewalls on two sides along an extension direction of the fin; and the adjacent semiconductor layers and the isolation layer between the adjacent semiconductor layers enclose a gate through hole; a second high-k gate dielectric layer, where the second high-k gate dielectric layer is on an inner wall surface of the gate through hole; a second metal gate, where the second metal gate completely fills the gate through hole; source/drain recesses, where the source/drain recesses are on the two sides of the fin; a source/drain doped layer, where the source/drain doped layer completely fills the source/drain recesses; an auxiliary recess is formed between the source/drain doped layer and the second metal gate; the auxiliary recess includes an opening facing the source/drain recess; the isolation layer is on a bottom of the auxiliary recess and does not completely fill the auxiliary recess; and the source/drain doped layer and the isolation layer enclose an air gap; a dielectric layer, where the dielectric layer covers sidewalls and a top of the source/drain doped layer; the dielectric layer includes a gate recess; and the gate recess exposes a top and sidewalls of the fin; a first high-k gate dielectric layer, where the first high-k gate dielectric layer is on sidewalls and a bottom surface of the gate recess; and a first metal gate, where the first metal gate completely fills the gate recess.

Optionally, the isolation layer is on the bottom and sidewalls of the auxiliary recess.

Optionally, along the extension direction of the fin, a depth of the auxiliary recess is from 2 nm to 8 nm.

Optionally, a material of the isolation layer is SiOCN.

Compared with the existing technology, the technical solution of the present disclosure has following advantages.

In the technical solution of the fabrication method of the semiconductor structure provided by the present disclosure, after forming the source/drain recesses, the sacrificial layer of the fin at the bottom of the dummy gate exposed by the source/drain recesses is etched to the form the auxiliary recesses on two sides of the sacrificial layer after etching along the extension direction of the fin. The isolation layer is formed on the bottoms of the auxiliary recesses. The isolation layer can support adjacent semiconductor layers in subsequent step of removing the sacrificial layer, and the isolation layer can isolate the source/drain doped layer and the channel. Furthermore, the isolation layer does not completely fill the auxiliary recess, and after the isolation layer is formed, the source/drain doped layer completely filling the source-drain recess is formed. The source/drain doped layer and the isolation layer enclose the air gap. The air gap is filled with air, and the dielectric constant of the air is lower, which is similar to the dielectric constant of a vacuum and has the approximate value of 1. Therefore, the air gap is beneficial for reducing the parasitic capacitance between the source/drain doped layer and subsequently formed metal gate and reducing the interaction between the source/drain doped layer and the metal gate.

### BRIEF DESCRIPTION OF THE DRAWINGS

FIGS. 1-7 illustrate structural schematics corresponding to certain stages of a fabrication method of a semiconductor structure.

FIGS. 8-30 illustrate structural schematics corresponding to certain stages of a fabrication method of a semiconductor structure according to embodiments of the present disclosure.

### DETAILED DESCRIPTION

It can be seen from the background that the performance of existing semiconductor structures still needs to be improved.

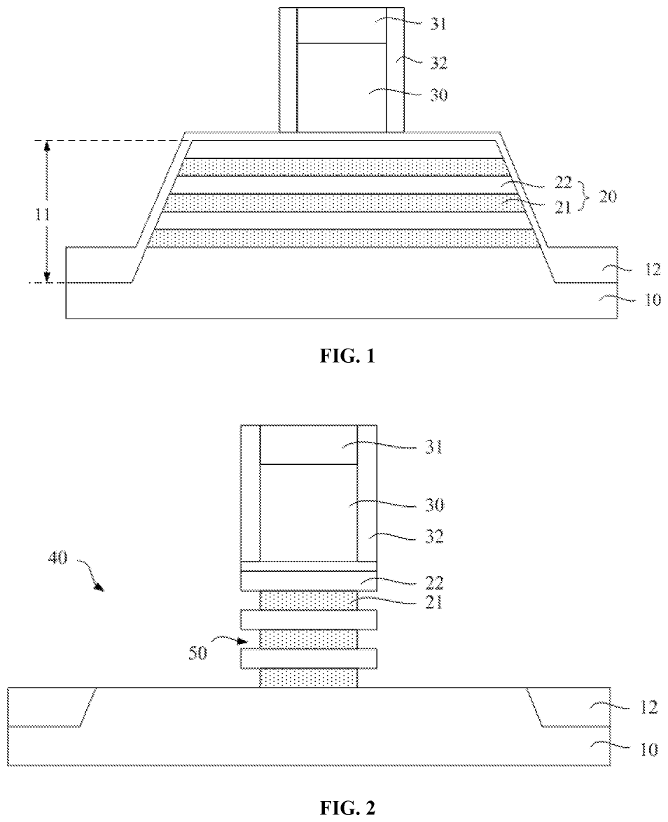

A fabrication method of a semiconductor structure is used for analysis. FIGS. 1-7 illustrate structural schematics corresponding to certain stages of a fabrication method of a semiconductor structure. The process for forming the semiconductor structure may mainly include following exemplary steps.

Referring to FIG. 1, a substrate 10 and a fin 11 protruding from the substrate 10 may be provided, the fin 11 may include a plurality of stacked structures 20 which are stacked over each other, and each stacked structure 20 may include a sacrificial layer 21 and a semiconductor layer 22 on the top of the sacrificial layer 21; and a padding oxide layer 12 may be formed on the top of the substrate 10 and on the top and the sidewall of the fin 11. A dummy gate 30 across the fin 11 may be formed, the dummy gate 30 may cover a portion of the top and a portion of the sidewall of the fin 11; a hard mask layer 31 may be on the top of the dummy gate a spacer 32 may be formed on the sidewall of the dummy gate 30 and the sidewall of the hard mask layer 31.

Referring to FIG. 2, the fin 11 (refer to FIG. 1) on two sides of the dummy gate may be etched to form source/drain recesses 40, and the source/drain recesses 40 may expose the fin 11 at the bottom of the dummy gate 30; the sacrificial layer 21 of the fin 11 at the bottom of the dummy gate 30 exposed by the source/drain recesses 40 may be etched to form auxiliary recesses 50 on two sides of the sacrificial layer 21 after etching along the extension direction of the fin 11.

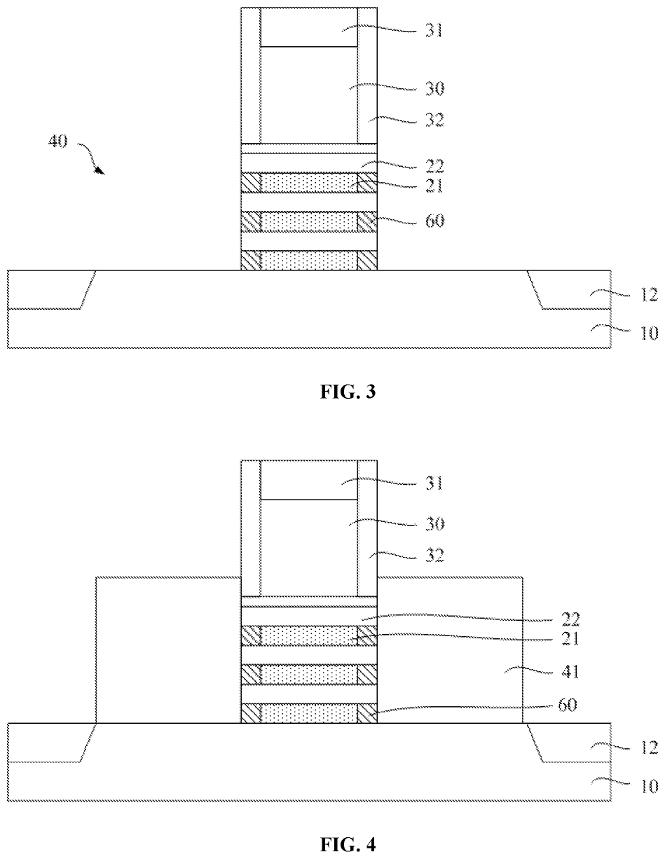

Referring to FIG. 3, an isolation layer 60 completely filling the auxiliary recess 50 may be formed.

Referring to FIG. 4, a source/drain doped layer 41 completely filling the source/drain recesses 40 may be formed.

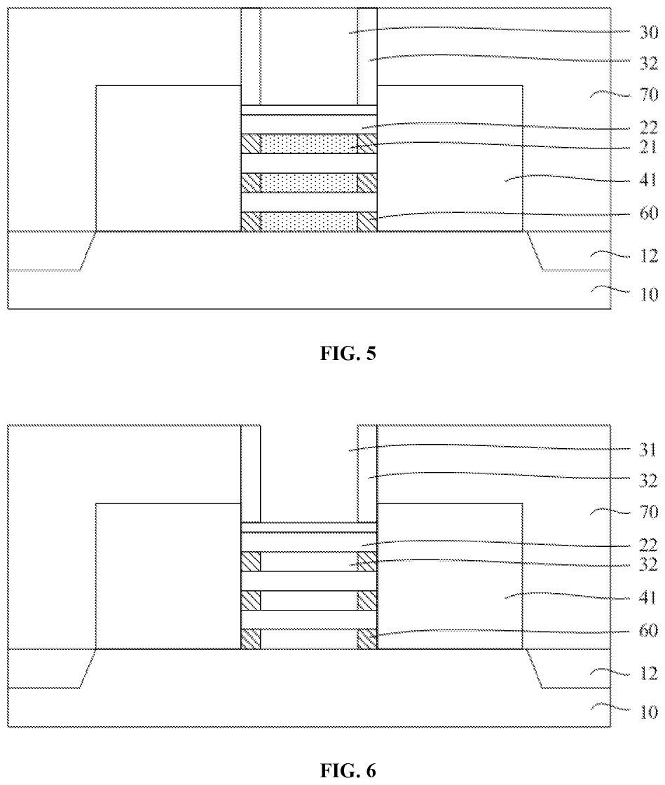

Referring to FIG. 5, a dielectric layer 70 covering the sidewalls and the top of the source/drain doped layer 41 and the sidewalls of the dummy gate 30 may be formed.

Referring to FIG. 6, the dummy gate 30 (refer to FIG. 5) may be removed to form a gate recess 31; the sacrificial layer 21 of the stacked structure 20 (refer to FIG. 5) may be removed; and adjacent semiconductor layers 22 and the isolation layer 60 between adjacent semiconductor layers 22 may enclose a gate through hole 32.

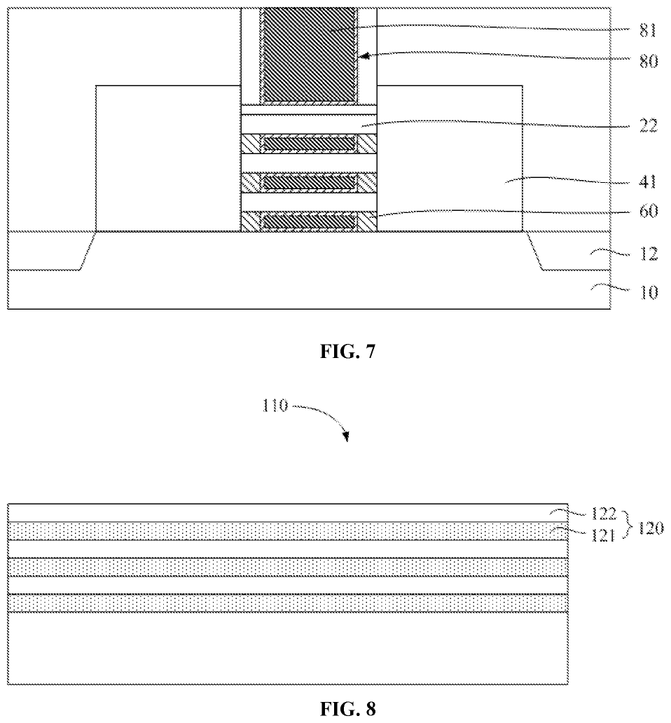

Referring to FIG. 7, a high-k gate dielectric layer 80 may be formed on the sidewalls and the bottom surface of the gate recess 31 (refer to FIG. 6) and the inner wall surface of the gate through hole 32; and a metal gate 81 completely filling the gate recess 31 and the gate through hole 32 may be formed.

The isolation layer 60 may completely fill the auxiliary recess 50, so that the dielectric constant of the material in the auxiliary recess 50 may be high, which may result in high parasitic capacitance of the source/drain doped layer 41 and affect the electrical performance of the semiconductor structure.

The inventors had studied the fabrication method of above-mentioned semiconductor structure. After creative work, the inventors had found that the isolation layer may be formed on the bottom of the auxiliary recess, and it is ensured that the isolation layer may not completely fill the auxiliary recess. On the one hand, the isolation layer may play a role in supporting adjacent semiconductor layer during the step of removing the sacrificial layer; on the other hand, an air gap may be formed between the source/drain doped layer and the isolation layer, and the air in the air gap may have a low dielectric constant, which may be beneficial for reducing the parasitic capacitance of the source/drain doped layer.

In order to make above-mentioned objectives, features and advantages of the present disclosure more comprehensible, specific embodiments of the present disclosure are described in detail below in conjunction with accompanying drawings.

FIGS. 8-30 illustrate structural schematics corresponding to certain stages of a fabrication method of a semiconductor structure according to embodiments of the present disclosure.

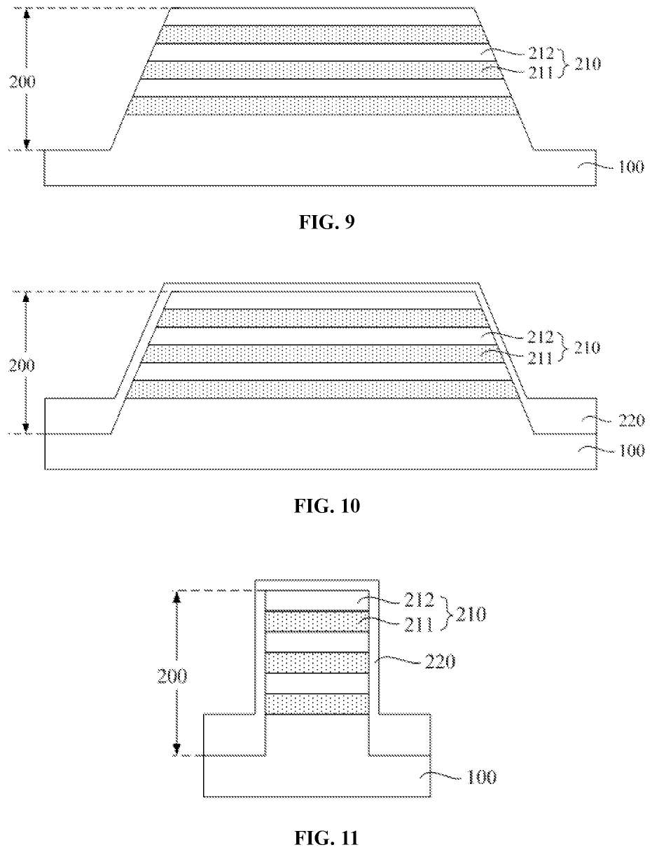

Referring to FIGS. 8-9, a substrate 100 and a fin 200 protruding from the substrate 100 may be provided. The fin 00 may include a plurality of stacked structures 210 which are stacked over each other; and each stacked structure 210 may include a sacrificial layer 211 and a semiconductor layer 212 on the top of the sacrificial layer 211.

The exemplary process steps of forming the substrate 100 and the fin 200 may include, as shown in FIG. 8, providing an initial substrate 110, where the initial substrate 110 may include a plurality of initial stacked structures 120 which are stacked over each other, and each initial stacked structure 120 may include a sacrificial film 121 and a semiconductor film 122 on the top of the sacrificial film 121; forming a patterned mask layer (not shown in drawings) on the top of the initial substrate 110; and as shown in FIG. 9, using the mask layer as a mask, etching the initial substrate 110 to form the fin 200, where remaining initial substrate 110 at the bottom of the fin 200 may be configured as the substrate 100.

The material of the semiconductor layer 212 may be different from the material of the sacrificial layer 211.

In one embodiment, the material of the sacrificial layer 211 may be silicon germanium. In other embodiments, the material of the sacrificial layer 211 may be silicon, germanium, silicon carbide, gallium arsenide or gallium indium.

In one embodiment, the material of the semiconductor layer 212 may be silicon. In other embodiments, the material of the semiconductor layer 212 may be germanium, silicon germanium, silicon carbide, gallium arsenide or indium gallium.

Referring to FIGS. 10-11, in one embodiment, after the fin 200 is formed, the method may further include forming a padding oxide layer 220 on the top of the substrate 100, and on the top and the sidewalls of the fin 200.

The cross-sectional direction in FIG. 10 is in parallel with the extension direction of the fin 200 and perpendicular to the surface of the substrate 100; and the cross-sectional direction in FIG. 11 is perpendicular to the extension direction of the fin 200.

The material of the padding oxide layer 220 may be silicon oxide.

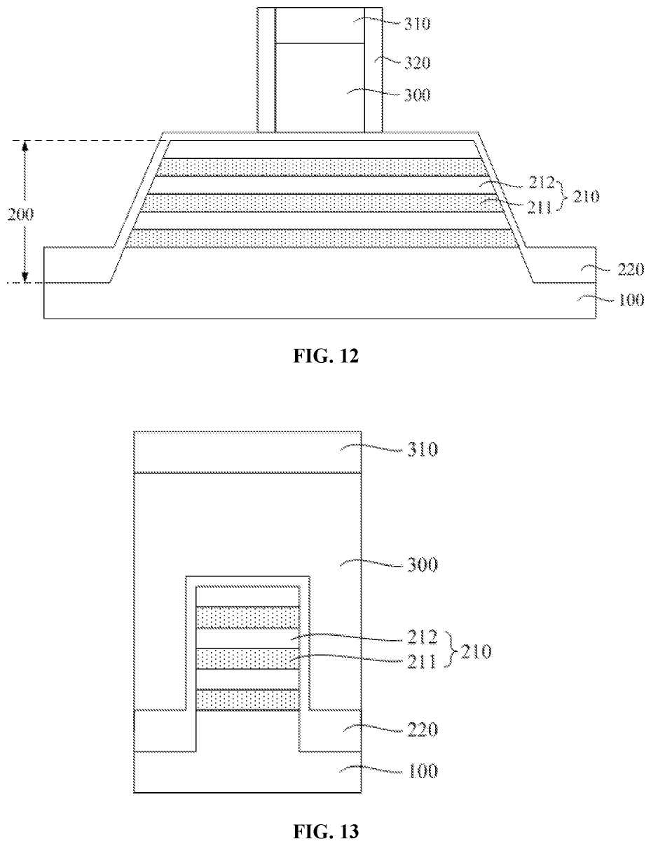

Referring to FIGS. 12-13, a dummy gate 300 across the fin 200 may be formed, and the dummy gate 300 may cover a portion of the top and a portion of the sidewall of the fin 200.

The cross-sectional direction in FIG. 12 is in parallel with the extension direction of the fin 200 and perpendicular to the surface of the substrate 100; and the cross-sectional direction in FIG. 13 is perpendicular to the extension direction of the fin 200.

In one embodiment, the material of the dummy gate 300 may be polysilicon. In other embodiments, the material of the dummy gate 300 may be amorphous carbon.

Exemplary step of forming the dummy gate 300 may further include forming a hard mask layer 310 on the top of the dummy gate 300.

In one embodiment, a dummy gate oxide layer (not shown in drawings) may be between the bottom of the dummy gate 300 and the surface of the fin 200.

In one embodiment, after forming the dummy gate 300, the method may further include forming a spacer 320 on the sidewall of the dummy gate 300 and the sidewall of the hard mask layer 310.

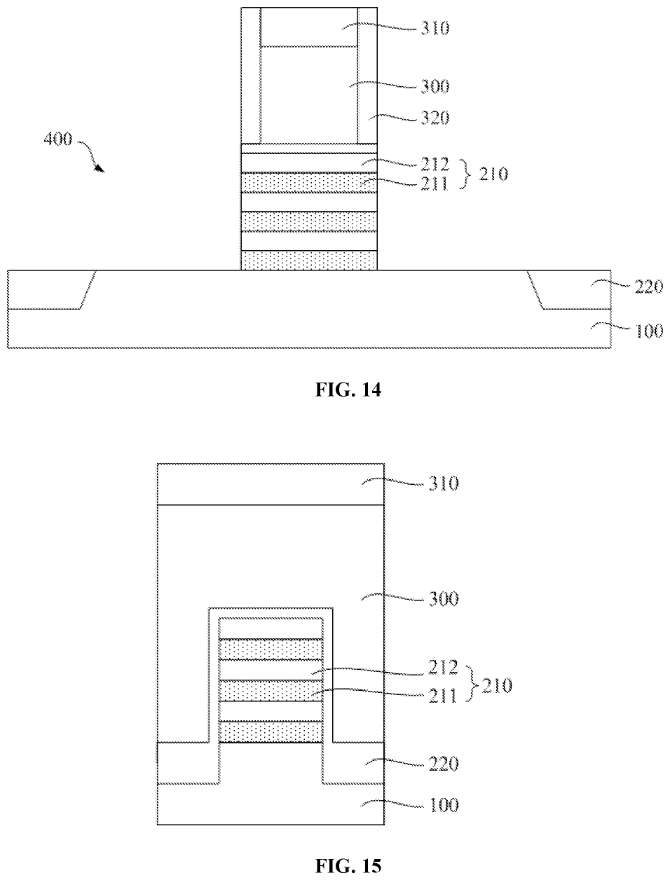

Referring to FIGS. 14-15, the fin 200 on two sides of the dummy gate 300 may be etched to form the source/drain recesses 400; and the source/drain recesses 400 may expose the fin 200 (refer to FIG. 12) at the bottom of the dummy gate 300.

The cross-sectional direction in FIG. 14 is in parallel with the extension direction of the fin 200 and perpendicular to the surface of the substrate 100; and the cross-sectional direction in FIG. 15 is perpendicular to the extension direction of the fin 200.

In one embodiment, the source/drain recesses 400 may expose the sacrificial layer 211 and the semiconductor layer 212 of each stacked structures 210 in the fin 200.

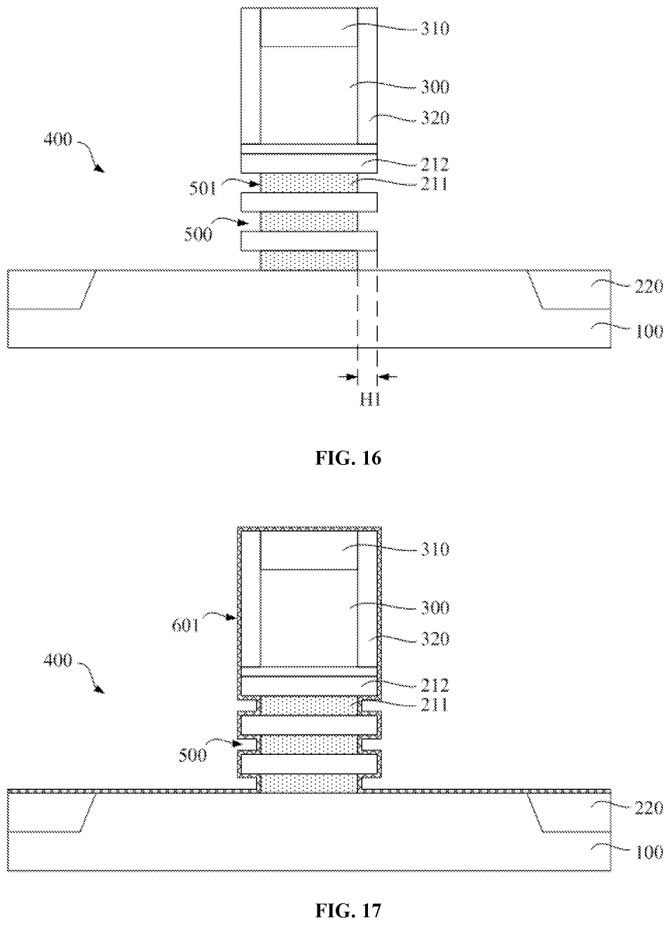

Referring to FIG. 16, the sacrificial layer 211 of the fin 200 at the bottom of the dummy gate 300 exposed by the source/drain recesses 400 may be etched to form auxiliary recesses 500 on two sides of the sacrificial layer 211 after etching along the extension direction of the fin 200. The auxiliary recess 500 may include an opening facing the source/drain recess 400, and sidewalls of the sacrificial layer 211 after etching along the extension direction of the fin 200 may form the bottoms 501 of the auxiliary recesses 500.

In one embodiment, along the extension direction of the fin 200, the depth H1 of the auxiliary recess 500 may be from 2 nm to 8 nm. If the depth H1 of the auxiliary recess 500 is greater than 8 nm, the width of the sacrificial layer 211 after etching along the extension direction of the fin 200 may be excessively small; the sacrificial layer 211 may be completely removed subsequently to form a gate through hole, and correspondingly, the width of the gate through hole along the extension direction of the fin 200 may be excessively small; and the gate through hole may be filled subsequently to form a second metal gate, which may result in the channel length to be excessively small. If the depth H1 of the auxiliary recess 500 is less than 2 nm, the volume of the auxiliary recess 500 may be excessively small; an isolation layer that does not completely fill the auxiliary recess 500 may be subsequently formed, which may result in the volume of the isolation layer to be excessively small; and the sacrificial layer 211 may be completed removed subsequently, which may affect the support effect of the isolation layer on adjacent semiconductor layer 212 and increase collapse risk of the semiconductor layer 212.

Referring to FIGS. 17 to 20, an isolation layer 600 may be formed on the bottom 501 of the auxiliary recess 500, and the isolation layer 600 may not completely fill the auxiliary recess 500.

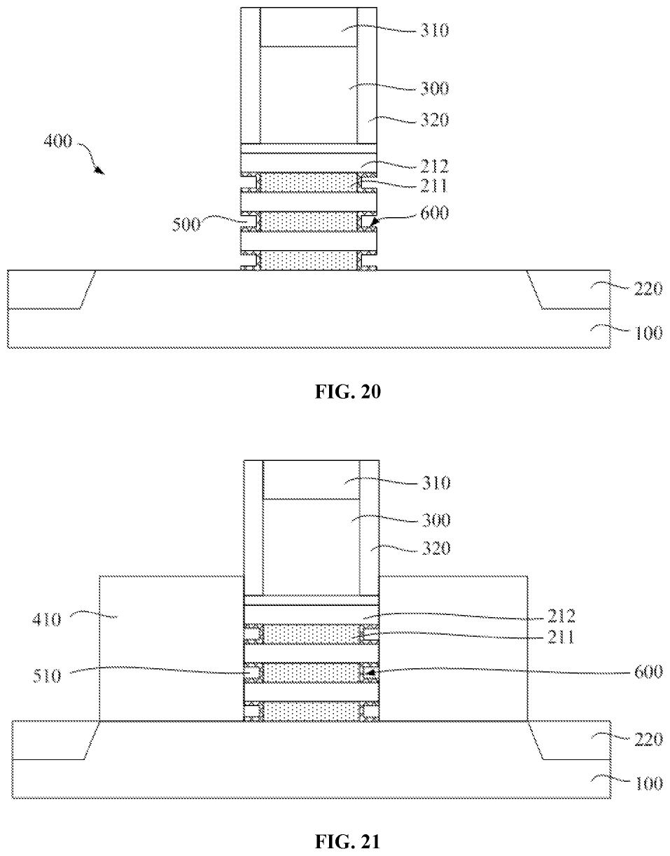

As shown in FIG. 20, in one embodiment, the isolation layer 600 may be on the bottom 501 (refer to FIG. 16) and the sidewalls of the auxiliary recess 500. A cross-section of the isolation layer 600 in parallel with the extension direction of the fin 200 may be U-shaped.

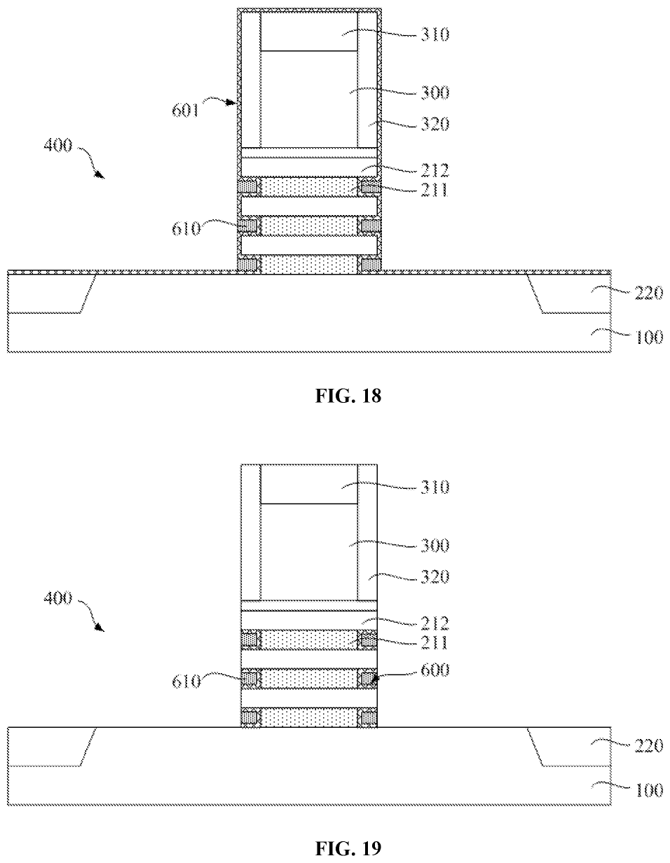

In one embodiment, the exemplary process steps of forming the isolation layer 600 may include, as shown in FIG. 17, forming an isolation film 601 on the sidewalls and the bottom of the source/drain recess 400, the sidewalls and the bottom of the auxiliary recess 500, and the sidewalls and the top of the dummy gate 300; as shown in FIG. 18, forming a filling layer 610 which completely fills the auxiliary recess 500; as shown in FIG. 19, removing the isolation film 601 on the sidewalls and the bottom of the source/drain recess 400 and the sidewalls and the top of the dummy gate 300, and forming the isolation layer 600 using a remaining portion of the isolation film 601; and as shown in FIG. 20, removing the filling layer 610.

In other embodiments, the isolation layer 600 may only be on the bottom 501 (refer to FIG. 16) of the auxiliary recess 500.

In one embodiment, the isolation film 601 may be formed by an atomic layer deposition process (refer to FIG. 17). Adjacent auxiliary recesses 500 may be arranged in a stepped shape, and the atomic layer deposition process may have a desirable step coverage, which be beneficial for ensuring the uniformity of the thickness of the isolation layer 600.

The material of the isolation layer 600 may be a low dielectric constant material, which may be beneficial for reducing the parasitic capacitance of the source/drain doped layer 410 subsequently formed in the source/drain recess 400. In one embodiment, the material of the isolation layer 600 may be SiOCN.

In one embodiment, the filling layer 610 may be formed by a chemical vapor deposition process (refer to FIG. 18). In other embodiments, the filling layer 610 may be formed by an atomic layer deposition.

In one embodiment, the exemplary process steps of forming the filling layer 610 may include forming a filling film on the isolation film 601, where the filling film completely fills the auxiliary recess 500; and removing the filling film by etching, where only the filling film in the auxiliary recess 500 may be retained to form the filling layer 610.

In one embodiment, the material of the filling layer 610 may be amorphous carbon which may be convenient to be removed and may not easily have residue.

In one embodiment, the filling layer 610 may be removed by a wet etching process.

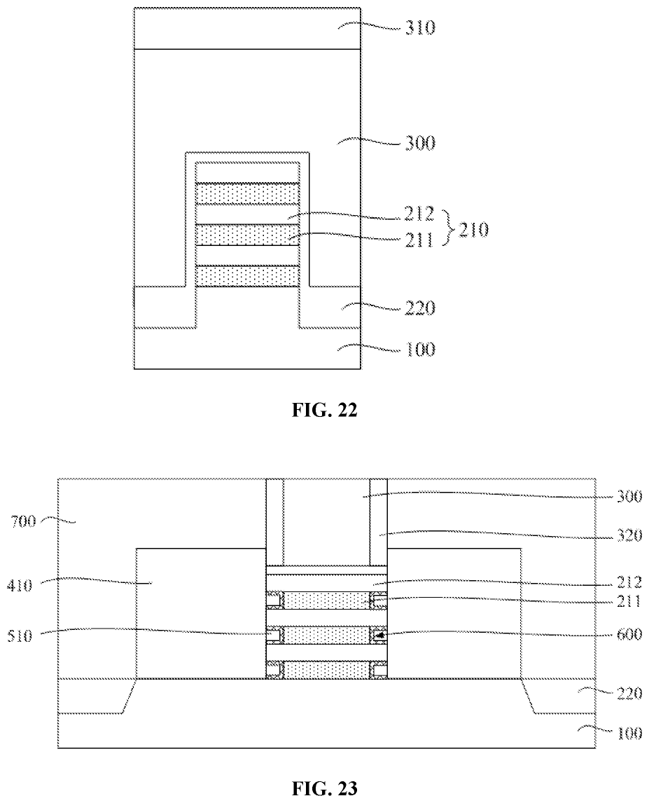

Referring to FIGS. 21-22, a source/drain doped layer 410 filling the source/drain recess 400 may be formed; the source/drain doped layer 410 may block the opening; and an air gap 510 may be formed between the source/drain doped layer 410 and the isolation layer 600.

The cross-sectional direction in FIG. 21 is in parallel with the extension direction of the fin 200 and perpendicular to the surface of the substrate 100; and the cross-sectional direction in FIG. 22 is perpendicular to the extension direction of the fin 200.

The air gap 510 may be filled with air. Compared with the material of the isolation layer filled in the auxiliary recess 500, the dielectric constant of the air may be low, which is similar to the dielectric constant of vacuum and has the approximate value of 1. Therefore, the air gap 510 may be beneficial for reducing the parasitic capacitance between the source/drain doped layer 410 and subsequently formed metal gate and reducing the interaction between the source/drain doped layer 410 and the metal gate.

In one embodiment, the semiconductor structure may be configured to form an NMOS transistor; the source/drain doped layer 410 may contain N-type ions; and the N-type ions may include P ions or C ions.

In other embodiments, the semiconductor structure may be configured to form a PMOS transistor; the source/drain doped layer 410 may contain P-type ions; and the P-type ions may include Ge ions.

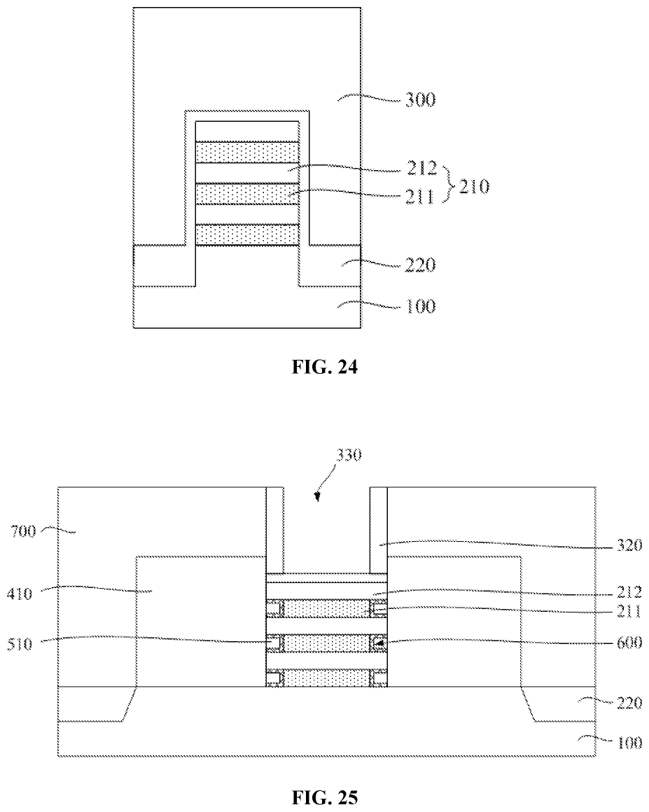

Referring to FIGS. 23-24, a dielectric layer 700 covering the sidewalls and top of the source/drain doped layer 410 and the sidewalls of the dummy gate 300 may be formed.

The cross-sectional direction in FIG. 23 is in parallel with the extension direction of the fin 200 and perpendicular to the surface of the substrate 100, and the cross-sectional direction in FIG. 24 is perpendicular to the extension direction of the fin 200.

In one embodiment, the material of the dielectric layer 700 may be silicon oxide. In other embodiments, the material of the dielectric layer 700 may also be silicon nitride, silicon carbide, silicon nitrogen carbide, silicon oxygen nitrogen carbide, silicon oxygen nitride, boron nitride or boron nitrogen carbide.

The exemplary process steps of forming the dielectric layer 700 may include forming a dielectric film (not shown in drawings) covering the sidewalls and top of the source/drain doped layer 410, the sidewalls of the dummy gate 300, and the top and sidewalls of the hard mask layer 310 (refer to FIG. 21); and removing the dielectric film higher than the top of the dummy gate 300, where the top of remaining dielectric film may be coplanar with the top of the dummy gate 300, and remaining dielectric film may be configured as the dielectric layer 700.

In one embodiment, the dielectric film may be formed by an atomic layer deposition process.

In one embodiment, the dielectric film higher than the top of the dummy gate 300 may be removed by a chemical mechanical polishing process.

In one embodiment, the process of removing the dielectric film higher than the top of the dummy gate 300 may also include removing the hard mask layer 310.

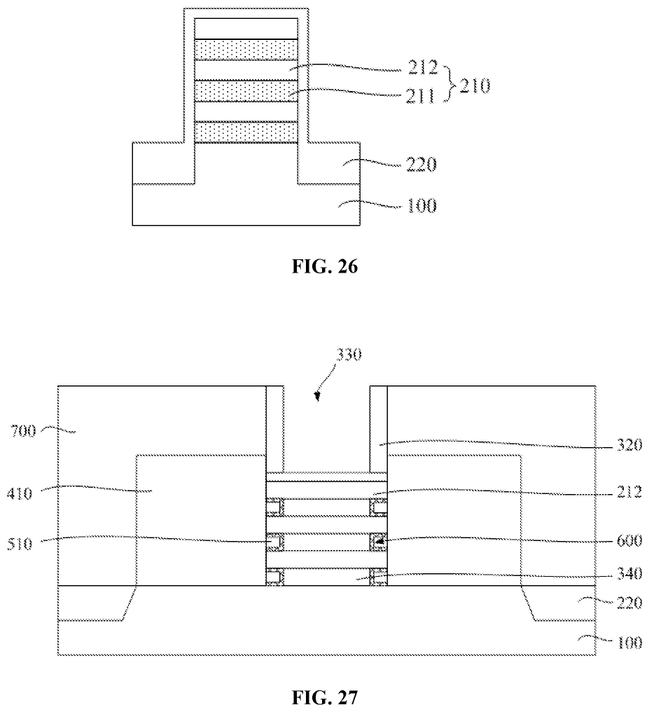

Referring to FIGS. 25-26, the dummy gate 300 (refer to FIG. 23) may be removed to form a gate recess 330.

The cross-sectional direction in FIG. 25 is in parallel with the extension direction of the fin 200 and perpendicular to the surface of the substrate 100; and the cross-sectional direction in FIG. 26 is perpendicular to the extension direction of the fin 200.

In one embodiment, after removing the dummy gate 300, the method may further include removing the dummy gate oxide layer exposed at the bottom of the gate recess 330.

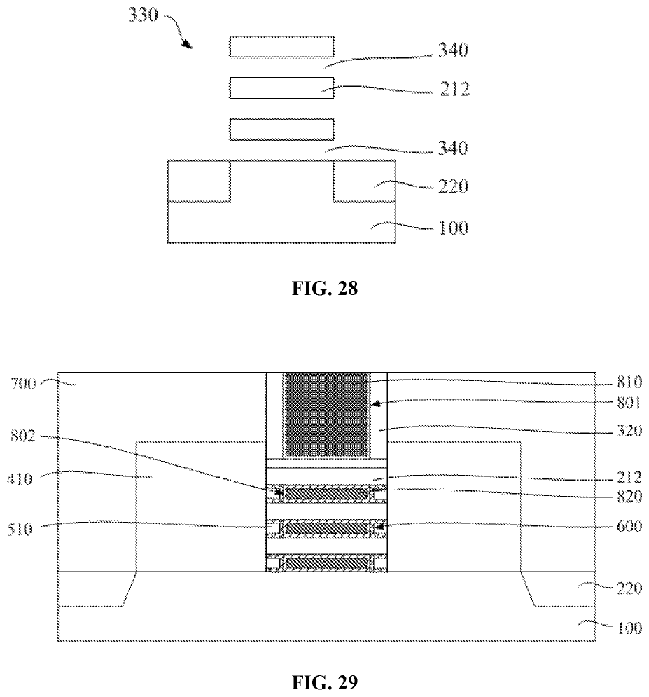

Referring to FIG. 27 and FIG. 28, after removing the dummy gate 300, remaining sacrificial layer 211 (refer to FIG. 25) may be removed, and adjacent semiconductor layers 212 and the isolation layer 600 between adjacent semiconductor layers 212 may enclose a gate through hole 340.

The cross-sectional direction in FIG. 27 is in parallel with the extension direction of the fin 200 and perpendicular to the surface of the substrate 100; and the cross-sectional direction in FIG. 28 is perpendicular to the extension direction of the fin 200.

In one embodiment, remaining sacrificial layer 211 may be removed by using a wet etching process.

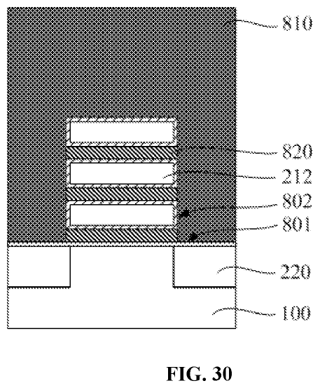

Referring to FIGS. 29-30, a first high-k gate dielectric layer 801 may be formed on the sidewalls and bottom surface of the gate recess 330, and a second high-k gate dielectric layer 802 may be formed on the inner wall surface of the gate through hole 340; after forming the first high-k gate dielectric layer 801 and the second high-k gate dielectric layer 802, a first metal gate 810 completely filling the gate recess 330 may be formed, and a second metal gate 820 completely filling the gate through hole 340 may be formed.

The cross-sectional direction in FIG. 29 is in parallel with the extension direction of the fin 200 and perpendicular to the surface of the substrate 100; and the cross-sectional direction in FIG. 30 is perpendicular to the extension direction of the fin 200.

In one embodiment, the first high-k gate dielectric layer 801 and the second high-k gate dielectric layer 802 may be formed in a same process step.

The first high-k gate dielectric layer 801 may be made of a same material as the second high-k gate dielectric layer 802. In one embodiment, the materials of the first high-k gate dielectric layer 801 and the second high-k gate dielectric layer 802 may be both HfO₂. In other embodiments, the materials of the first high-k gate dielectric layer 801 and the second high-k gate dielectric layer 802 may also be HfSiO, HfSiON, HfTaO, HfSiO, HfZrO, ZrO₂ or Al₂O₃.

In one embodiment, the first metal gate 810 and the second metal gate 820 may be formed in a same process step. The first metal gate 810 and the second metal gate 820 may form a metal gate.

The materials of the first metal gate 810 and the second metal gate 820 may be same. In one embodiment, the materials of the first metal gate 810 and the second metal gate 820 may be both Cu. In other embodiments, the materials of the first metal gate 810 and the second metal gate 820 may also be W or Ag.

Referring to FIG. 29, the present disclosure further provides a semiconductor structure obtained by above-mentioned fabrication method. The semiconductor structure may include the substrate 100 and the fin protruding from the substrate 100, where the fin may include the plurality of stacked semiconductor layers 212, and a space may be between adjacent semiconductor layers 212; the isolation layer 600, where one isolation layer 600 may be between adjacent semiconductor layers 212 and at each of the sidewalls on two sides along the extension direction of the fin, and adjacent semiconductor layers 212 and the isolation layer 600 between adjacent semiconductor layers 212 may enclose the gate through hole; the second high-k gate dielectric layer 802, where the second high-k gate dielectric layer 802 may be on the inner wall surface of the gate through hole; the second metal gate 820, where the second metal gate 820 may completely fill the gate through hole; the source/drain recesses, where the source/drain recesses may be on two sides of the fin; the source/drain doped layer 410, where the source/drain doped layer 410 may completely fill the source/drain recesses, the auxiliary recess may be formed between the source/drain doped layer 410 and the second metal gate 820, the auxiliary recess may include an opening facing the source/drain recess 400, the isolation layer 600 may be on the bottom of the auxiliary recess and may not completely fill the auxiliary recess, and the source/drain doped layer 410 and the isolation layer 600 may enclose the air gap 510; the dielectric layer 700, where the dielectric layer 700 may cover the sidewalls and the top of the source/drain doped layer 410, the dielectric layer 700 may include the gate recess, and the gate recess may expose the top and the sidewalls of the fin; the first high-k gate dielectric layer 801, where the first high-k gate dielectric layer 801 may be on the sidewalls and the bottom surface of the gate recess; and the first metal gate 810, where the first metal gate 810 may completely fill the gate recess.

In one embodiment, along the extension direction of the fin, the depth of the auxiliary recess 500 may be from 2 nm to 8 nm.

In one embodiment, the isolation layer 600 may be on the bottom and the sidewalls of the auxiliary recess. A cross-section of the isolation layer 600 in parallel with the extension direction of the fin may be U-shaped.

In other embodiments, the isolation layer 600 may be only on the bottom of the auxiliary recess 500.

In one embodiment, the material of the isolation layer 600 may be SiOCN.

The first metal gate 810 and the second metal gate 820 may form the metal gate. The air in the air gap 510 may have a low dielectric constant, which may be beneficial for reducing the parasitic capacitance between the source/drain doped layer 410 and the metal gate.

Although the present disclosure has been disclosed above, the present disclosure may not be limited thereto. Any changes and modifications may be made by those skilled in the art without departing from the spirit and scope of the present disclosure. Therefore, the scope of the present disclosure should be determined by the scope defined by appended claims.

1. A fabrication method of a semiconductor structure, comprising:
providing a substrate and a fin protruding from the substrate, wherein the fin includes a plurality of stacked structures; and each stacked structure includes a sacrificial layer and a semiconductor layer on a top of the sacrificial layer;
forming a dummy gate across the fin, wherein the dummy gate covers a portion of a top of the fin and a portion of a sidewall of the fin;
etching the fin on two sides of the dummy gate to form source/drain recesses, wherein the source/drain recesses expose the fin at a bottom of the dummy gate;
etching the sacrificial layer of the fin at the bottom of the dummy gate exposed by the source/drain recesses to form auxiliary recesses on two sides of the sacrificial layer after etching along an extension direction of the fin, wherein an auxiliary recess includes an opening facing a source/drain recess, and sidewalls on the two sides of the sacrificial layer after etching along the extension direction of the fin form bottoms of the auxiliary recesses;
forming an isolation layer on the bottoms of the auxiliary recesses, wherein the isolation layer does not completely fill the auxiliary recesses;
forming a source/drain doped layer completely filling the source/drain recesses, wherein the source/drain doped layer blocks the opening; and the source/drain doped layer and the isolation layer enclose an air gap;
forming a dielectric layer covering sidewalls and a top of the source/drain doped layer and sidewalls of the dummy gate;
removing the dummy gate to form a gate recess;
after removing the dummy gate, removing a remaining portion of the sacrificial layer, wherein adjacent semiconductor layers and the isolation layer between the adjacent semiconductor layers enclose a gate through hole;
forming a first high-k gate dielectric layer on sidewalls and a bottom surface of the gate recess, and forming a second high-k gate dielectric layer on an inner wall surface of the gate through hole; and
forming a first metal gate completely filling the gate recess and forming a second metal gate completely filling the gate through hole.

2. The method according to claim 1, wherein:
the isolation layer is on the bottoms and sidewalls of the auxiliary recesses; and forming the isolation layer includes:
forming an isolation film on sidewalls and bottoms of the source/drain recesses, the sidewalls and the bottoms of the auxiliary recesses, and the sidewalls and a top of the dummy gate;
forming a filling layer completely filling the auxiliary recesses;
removing the isolation film on the sidewalls and the bottoms of the source/drain recesses and the sidewalls and the top of the dummy gate, and forming the isolation layer using a remaining portion of the isolation film; and
removing the filling layer.

3. The method according to claim 2, wherein:
the isolation film is formed by an atomic layer deposition process.

4. The method according to claim 2, wherein:
the filling layer is formed by a chemical vapor deposition process or an atomic layer deposition process.

5. The method according to claim 2, wherein:
the filling layer is removed by using a wet etching process.

6. The method according to claim 2, wherein:
a material of the filling layer is amorphous carbon.

7. The method according to claim 1, wherein:
along the extension direction of the fin, a depth of the auxiliary recess is from 2 nm to 8 nm.

8. The method according to claim 1, wherein:
a material of the isolation layer is SiOCN.

9. The method according to claim 1, wherein:
forming the dummy gate further includes forming a hard mask layer on a top of the dummy gate.

10. The method according to claim 9, wherein after forming the dummy gate and before forming the source/drain recesses, further including:
forming a spacer on a sidewall of the dummy gate and a sidewall of the hard mask layer.

11. The method according to claim 1, wherein:
a material of the sacrificial layer is silicon germanium, silicon, germanium, silicon carbide, gallium arsenide or gallium indium; and a material of the semiconductor layer is silicon, germanium, silicon germanium, silicon carbide, gallium arsenide or gallium indium.

12. The method according to claim 1, wherein before forming the dummy gate, further including:
forming a padding oxide layer on a top of the substrate, the top and the sidewall of the fin.

13. A semiconductor structure, comprising:
a substrate and a fin protruding from the substrate, wherein the fin includes a plurality of stacked semiconductor layers, and a gap is between adjacent semiconductor layers;
an isolation layer, wherein one isolation layer is between the adjacent semiconductor layers and at each of sidewalls on two sides along an extension direction of the fin; and the adjacent semiconductor layers and the isolation layer between the adjacent semiconductor layers enclose a gate through hole;
a second high-k gate dielectric layer, wherein the second high-k gate dielectric layer is on an inner wall surface of the gate through hole;
a second metal gate, wherein the second metal gate completely fills the gate through hole;
source/drain recesses, wherein the source/drain recesses are on the two sides of the fin;
a source/drain doped layer, wherein the source/drain doped layer completely fills the source/drain recesses; an auxiliary recess is formed between the source/drain doped layer and the second metal gate; the auxiliary recess includes an opening facing the source/drain recess; the isolation layer is on a bottom of the auxiliary recess and does not completely fill the auxiliary recess; and the source/drain doped layer and the isolation layer enclose an air gap;
a dielectric layer, wherein the dielectric layer covers sidewalls and a top of the source/drain doped layer; the dielectric layer includes a gate recess; and the gate recess exposes a top and sidewalls of the fin;
a first high-k gate dielectric layer, wherein the first high-k gate dielectric layer is on sidewalls and a bottom surface of the gate recess; and
a first metal gate, wherein the first metal gate completely fills the gate recess.

14. The structure according to claim 13, wherein:
the isolation layer is on the bottom and sidewalls of the auxiliary recess.

15. The structure according to claim 13, wherein:
along the extension direction of the fin, a depth of the auxiliary recess is from 2 nm to 8 nm.

16. The structure according to claim 13m, wherein:
a material of the isolation layer is SiOCN.
